(19) United States
(12) Patent Application Publication
(10) Pub. No.: US 2014/0029226 A1
(43) Pub. Date: Jan. 30, 2014

(54) DISPLAY DEVICE

(71) Applicant: Japan Display Inc., Tokyo (JP)

(72) Inventors: Hideaki ABE, Chiba (JP); Yasushi NAKANO, Tokyo (JP); Hitoshi KAWAGUCHI, Mobara (JP)

(73) Assignee: Japan Display Inc.

(21) Appl. No.: 13/943,087

(22) Filed: Jul. 16, 2013

(30) Foreign Application Priority Data
Jul. 25, 2012 (JP) 2012-164903

(51) Int. Cl. H05K 1/11

(52) U.S. Cl. CPC H05K 1/111
USPC 361/773

(57) ABSTRACT

An integrated circuit chip includes first and second electrode terminals electrically connected to an internal circuit, and a dummy bump arranged between the first and second electrode terminals on a back surface thereof. A wiring pattern includes first lines electrically connected to the first electrode terminals below the back surface of the integrated circuit chip and extend in the direction toward a display region outside the integrated circuit chip, and second lines electrically connected to the second electrode terminals below the back surface of the integrated circuit chip and extend in the direction opposite to the display region outside the integrated circuit chip. The dummy bump is configured to avoid at least one of the electrical connection between the dummy bump and all of the first lines and all of the second lines and the electrical connection between the dummy bump and the internal circuit.

### CROSS-REFERENCE TO RELATED APPLICATION

The present application claims priority from Japanese application JP2012-164903 filed on Jul. 25, 2012, the content of which is hereby incorporated by reference into this application.

### BACKGROUND OF THE INVENTION

1. Field of the Invention

The present invention relates to a display device.

2. Description of the Related Art

There has been known a technique where an integrated circuit chip which incorporates a driver therein is mounted on a liquid crystal display panel (Japanese Patent No. 3824845). There has been also known a technique where an anisotropic conductive film is used in mounting an integrated circuit chip. In a mounting process, the integrated circuit chip is heated and pressed by way of the anisotropic conductive film.

Electrodes are arranged on edge portions of a back surface of the integrated circuit chip along two sides arranged opposite to each other, and a bump is provided to each electrode. However, no bumps are present at the center of the back surface. Accordingly, there has been a case where the center of the integrated circuit chip is deflected when pressed. When the center of the integrated circuit chip is deflected, all of the back surface is curved thus giving rise to a possibility that the bump will be inclined causing a failure in electrical connection.

### SUMMARY OF THE INVENTION

It is an object of the invention to provide a display device where the occurrence of electrical connection failure can be prevented by preventing the deflection of an integrated circuit chip.

(1) According to one aspect of the invention, there is provided a display device which includes: a display panel which has a display region; a wiring pattern which is formed on the display panel; and an integrated circuit chip which includes an internal circuit and is mounted on the display panel, wherein the integrated circuit chip is configured such that the integrated circuit chip has aback surface including a first side and a second side which are arranged opposite to each other, the first side is arranged adjacent to the display region, and the integrated circuit chip includes: a plurality of first electrode terminals which are arranged on an edge portion along the first side and are electrically connected to the internal circuit; a plurality of second electrode terminals which are arranged on an edge portion along the second side and are electrically connected to the internal circuit; and a first bump which is arranged between the plurality of first electrode terminals and the plurality of second electrode terminals on the back surface thereof, the wiring pattern includes: a plurality of first lines which are electrically connected to the plurality of first electrode terminals below the back surface of the integrated circuit chip and extend in the direction toward the display region outside the integrated circuit chip; and a plurality of second lines which are electrically connected to the plurality of second electrode terminals below the back surface of the integrated circuit chip and extend in the direction opposite to the display region outside the integrated circuit chip, and the first bump is arranged so as to avoid at least one of the electrical connection between the first bump and all of the first lines and all of the second lines and the electrical connection between the first bump and the internal circuit. According to the invention, the first bump functions as a spacer, thus preventing the deflection of an integrated circuit chip and thereby the occurrence of electrical connection failure can be prevented.

(2) The display device having the constitution described in (1) may be configured such that in a state where the back surface is divided into four regions by evenly dividing a distance between the first side and the second side by four, the plurality of first electrode terminals are arranged in the region closest to the first side, the plurality of second electrode terminals are arranged in the region closest to the second side, and the first bump is arranged in two remaining regions.

(3) The display device having the constitution described in (1) may be configured such that in a state where the back surface is divided into eight regions by evenly dividing a distance between both ends of the first side and the second side by eight, the first bump is arranged in second and third regions and in sixth and seventh regions as counted from one of both ends.

(4) The display device having the constitution described in any one of (1) to (3) may be configured such that the wiring pattern further includes a land which is arranged away from the plurality of first lines and the plurality of second lines, and the land is arranged within a region where the land faces the back surface of the integrated circuit chip, and the land is electrically connected with the first bump.

(5) The display device having the constitution described in any one of (1) to (3) may be configured such that the display device further includes: conductive particles which are interposed between the plurality of first electrode terminals and the plurality of first lines as well as between the plurality of second electrode terminals and the plurality of second lines respectively.

(6) The display device having the constitution described in (4) may be configured such that the display device further includes: conductive particles which are interposed between the plurality of first electrode terminals and the plurality of first lines as well as between the plurality of second electrode terminals and the plurality of second lines respectively; and conductive particles which are interposed between the first bump and the land.

(7) The display device having the constitution described in any one of (1) to (6) may be configured such that the plurality of first electrode terminals and the plurality of second electrode terminals form second bumps respectively, and the first bump is formed using the same material as the second bumps and has the same height as the second bumps.

(8) The display device having the constitution described in any one of (1) to (7) may be configured such that the internal circuit includes an active element.

(9) The display device having the constitution described in any one of (1) to (8) may be configured such that the first bump is arranged so as to avoid the electrical connection between the first bump and all of the first lines and all of the second lines.

(10) The display device having the constitution described in any one of (1) to (9) may be configured such that the first bump is arranged so as to avoid the electrical connection between the first bump and the internal circuit.

(11) The display device having the constitution described in any one of (1) to (10) may be configured such that a resin is interposed between the integrated circuit chip and the display panel.

(12) The display device having the constitution described in (2) may be configured such that in a state where the back surface is divided into eight regions by evenly dividing a distance between both ends of the first side and the second side by eight, the first bump is arranged in second and third regions and in sixth and seventh regions as counted from one of both ends.

### BRIEF DESCRIPTION OF THE DRAWINGS

FIG. 1 is a perspective view showing the schematic constitution of a display device according to an embodiment of the invention;

FIG. 2 is a view showing an edge portion of a liquid crystal display panel;

FIG. 3 is a view showing a back surface of an integrated circuit chip;

FIG. 4 is a cross-sectional view of the structure shown in FIG. 2 taken along a line IV-IV;

FIG. 5 is a plan view showing a connection state between first electrode terminals and first lines and a connection state between second electrode terminals and second lines; and

FIG. 6 is a view showing a modification of the embodiment of the invention.

### DETAILED DESCRIPTION OF THE INVENTION

Hereinafter, a display device according to an embodiment of the invention is explained in conjunction with drawings.

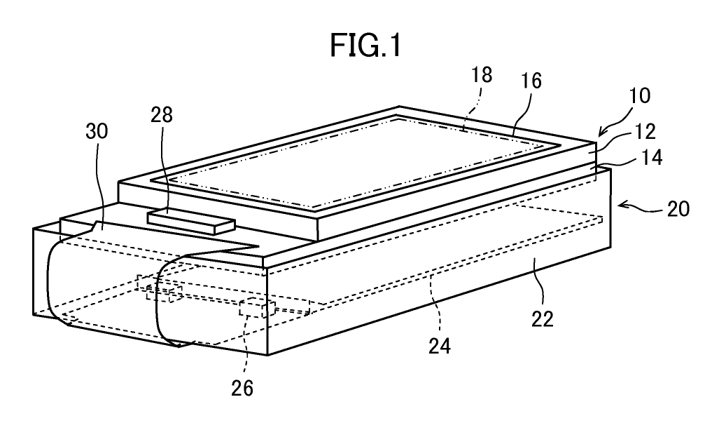

FIG. 1 is a perspective view showing the schematic constitution of the display device according to the embodiment of the invention. Although the embodiment where the invention is applied to a liquid crystal display device is explained hereinafter, the invention is also applicable to display devices other than the liquid crystal display device (for example, an EL (Electro Luminescence) display device).

The liquid crystal display device includes a liquid crystal display panel 10 which is one example of a display panel. The liquid crystal display panel 10 includes a first substrate 12 and a second substrate 14 which are made to overlap with each other. The first substrate 12 and the second substrate 14 are respectively made of a light transmissive substrate made of glass or the like, and liquid crystal not shown in the drawing is interposed between both substrates. The first substrate 12 is a color filter substrate, and the second substrate 14 is a TFT (Thin Film Transistor) substrate (or an array substrate) which includes thin film transistors, pixel electrodes, lines and the like not shown in the drawing. A polarizer 16 is laminated to the first substrate 12, and a polarizer not shown in the drawing is also laminated to the second substrate 14. The liquid crystal display panel 10 includes a display region 18.

The liquid crystal display device includes a backlight unit 20 which supplies light to the liquid crystal display panel 10. The backlight unit 20 includes a frame 22 to which the liquid crystal display panel 10 is fixed. In the frame 22, a light guide plate 24, a light source 26 (for example, light emitting diode), optical sheets (diffusion sheet, prism sheet and the like) not shown in the drawing which are positioned on the light guide plate 24 (on a liquid crystal display panel 10 side), and a reflection sheet not shown in the drawing which is positioned below the light guide plate 24 (on a side opposite to the group of optical sheets) are housed.

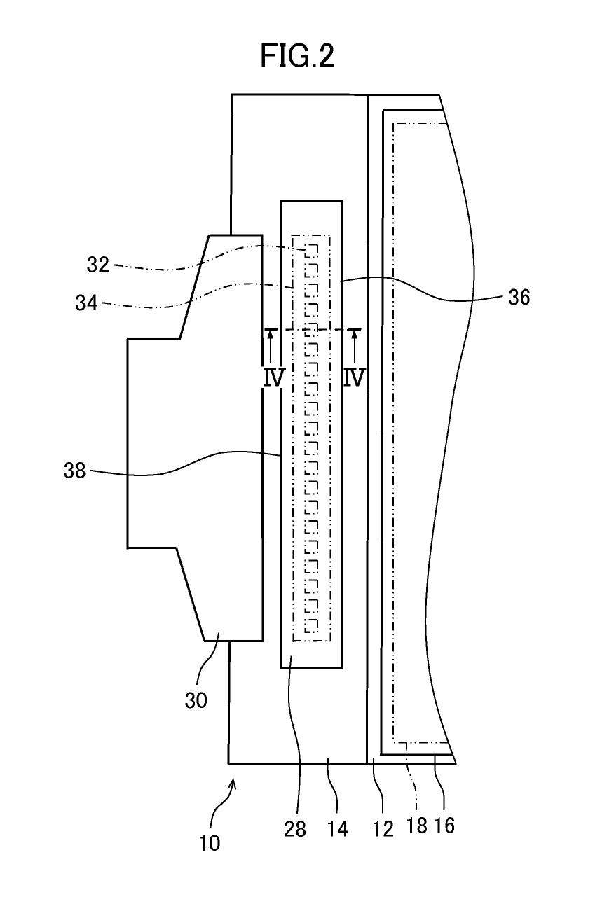

FIG. 2 is a view showing an edge portion of the liquid crystal display panel 10. The first substrate 12 and the second substrate 14 of the liquid crystal display panel 10 have rectangular planar shapes which differ in size from each other. One side of the second substrate 14 projects from one side of the first substrate 12. An integrated circuit chip 28 which incorporates a driver circuit for driving liquid crystal therein is mounted on a portion of the second substrate 14 projecting from the first substrate 12. A flexible printed circuit board 30 is mounted on such a projecting portion. The flexible printed circuit board 30 is bent outside the frame 22, and extends toward a lower side of the frame 22 (a side of the frame 22 opposite to the liquid crystal display panel 10). The light source 26 is mounted on the flexible printed circuit board 30 and is arranged adjacent to an edge portion of the light guide plate 24.

The integrated circuit chip 28 has a rectangular planar shape, and has a length of approximately 25 mm to 30 mm in the long-axis direction. Due to the increase in the number of output terminals which is brought about by the realization of higher resolution of display, a length of the integrated circuit chip 28 in the long-axis direction is set to 20 mm or more. A width of the integrated circuit chip 28 in the short-axis direction is approximately 0.7 mm to 2.0 mm (for example, 1 mm or more). The integrated circuit chip 28 is thin with a thickness of approximately 0.15 mm to 0.25 mm (for example, 0.2 mm or less). Because of such thin thickness, the integrated circuit chip 28 is liable to be deformed by a pressure applied to the integrated circuit chip 28 at the time of mounting the integrated circuit chip 28 using a pressure bonding head.

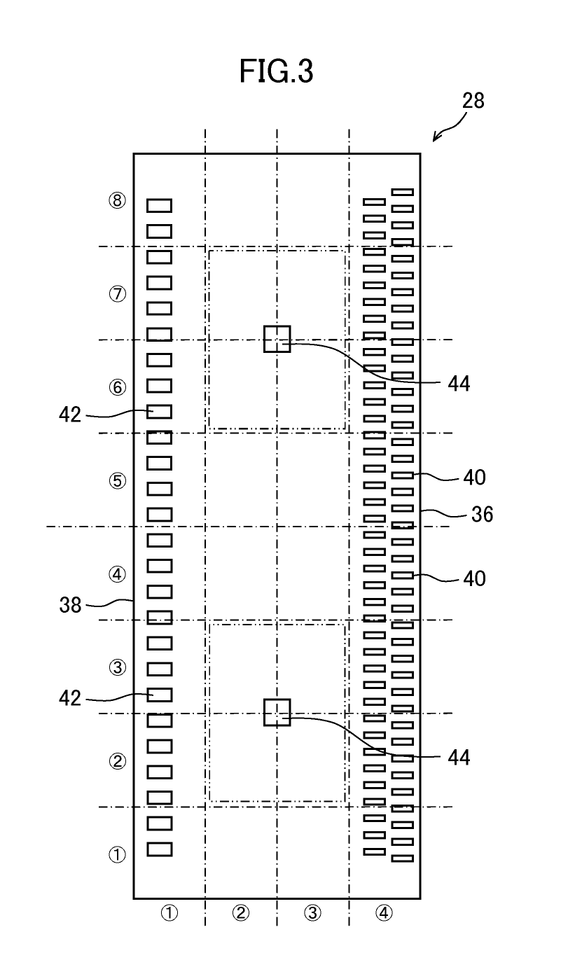

FIG. 3 is a view showing a back surface of the integrated circuit chip 28. The integrated circuit chip 28 has an internal circuit 34 which includes an active element 32 (see FIG. 2). The back surface of the integrated circuit chip 28 includes a first side 36 and a second side 38 which are arranged opposite to each other. As shown in FIG. 2, the first side 36 is arranged adjacent to the display region 18, while the second side 38 is arranged adjacent to the flexible printed circuit board 30.

A plurality of first electrode terminals 40 are arranged on an edge portion of the back surface along the first side 36, and are electrically connected to the internal circuit 34 (see FIG. 2). The first electrode terminals 40 are output-side terminals leading to the display region 18. The plurality of first electrode terminals 40 are arranged in plural rows (two rows in FIG. 3) in a staggered manner. A plurality of second electrode terminals 42 are arranged on an edge portion of the back surface along the second side 38, and are electrically connected to the internal circuit 34 (see FIG. 2). The second electrode terminals 42 are input-side terminals into which signals are inputted from the outside. A distance between the first electrode terminal 40 and the second electrode terminal 42 which are arranged closest to each other is approximately 0.3 mm to 1.6 mm (for example, 0.6 mm or more).

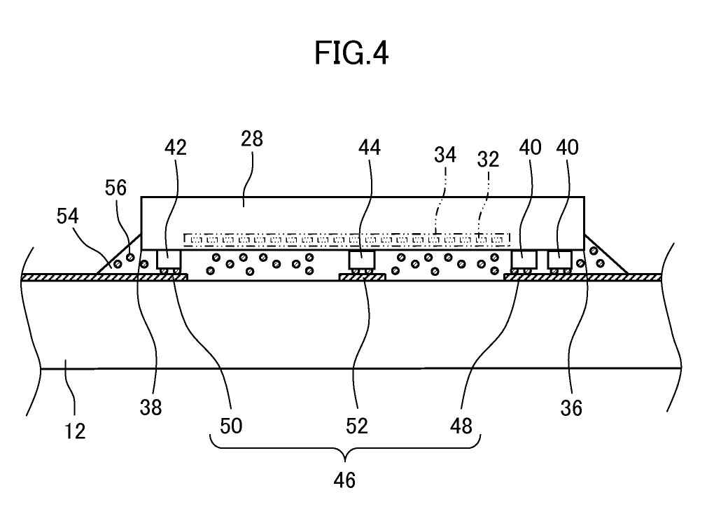

FIG. 4 is a cross-sectional view of the structure shown in FIG. 2 taken along a line IV-IV. The plurality of first electrode terminals 40 and the plurality of second electrode terminals 42 are bumps. Dummy bumps 44 are mounted on the back surface between the plurality of first electrode terminals 40 and the plurality of second electrode terminals 42. The dummy bumps 44 are arranged so as to avoid the electrical connection between the dummy bumps 44 and the internal circuit 34. The dummy bumps 44 are formed using the same material as the plurality of first electrode terminals 40 and the plurality of second electrode terminals 42, and have the same height as the plurality of first electrode terminals 40 and the plurality of second electrode terminals 42. It is preferable that an area of a distal end surface of the dummy bump 44 be 100 μm² or more, and it is more preferable that longitudinal and lateral lengths of the distal end surface of the dummy bump 44 be 10 μm or more respectively.

As shown in FIG. 3, in a state where the back surface is divided into four regions by evenly dividing a distance (distance in the short-axis direction) between the first side 36 and the second side 38 by four, the plurality of first electrode terminals 40 are arranged in the region closest to the first side 36. The plurality of second electrode terminals 42 are arranged in the region closest to the second side 38.

The region where the dummy bumps 44 are arranged is constituted of two regions at the center in a state where the back surface is divided into four regions by evenly dividing the back surface by four in the short-axis direction. Further, in a state where the back surface is divided into eight by evenly dividing a distance (distance in the long-axis direction) between both ends of the first side 36 and the second side 38, the region where the dummy bump 44 is arranged is positioned in second and third regions and the dummy bump 44 is arranged in sixth and seventh regions as counted from either of the both ends of the first side 36 and the second side 38.

As shown in FIG. 4, the liquid crystal display panel 10 has a wiring pattern 46. The wiring pattern 46 includes a plurality of first lines 48 and a plurality of second lines 50. The plurality of first lines 48 are formed in an extending manner from the inside to the outside of the display region 18 (FIG. 2), and constitute signal lines for transmitting video signals, for example. The plurality of first lines 48 extend in the direction toward the display region 18 outside the integrated circuit chip 28. The plurality of first lines 48 are electrically connected to the plurality of first electrode terminals 40 below the back surface of the integrated circuit chip 28.

The plurality of second lines 50 extend so as to be connected to the flexible printed circuit board 30 (FIG. 2). The plurality of second lines 50 extend in the direction opposite to the display region 18 outside the integrated circuit chip 28. The plurality of second lines 50 are electrically connected to the plurality of second electrode terminals 42 below the back surface of the integrated circuit chip 28.

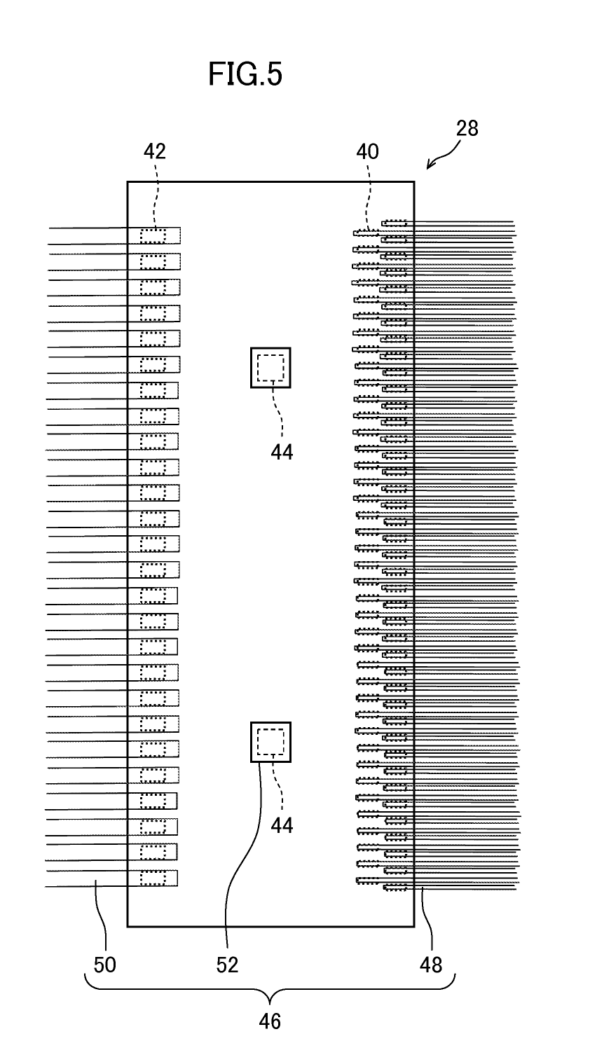

FIG. 5 is a plan view showing a connection state between the first electrode terminals 40 and the first lines 48 and a connection state between the second electrode terminals 42 and the second lines 50.

The wiring pattern 46 includes lands 52 which are arranged away from the plurality of first lines 48 and the plurality of second lines 50. The lands 52 are arranged within a region where the lands face the back surface of the integrated circuit chip 28 in an opposed manner. The land 52 is electrically connected with the dummy bump 44. The dummy bumps 44 are arranged so as to avoid at least one of the electrical connection between the dummy bumps 44 and all of the first lines 48 and all of the second lines 50 and the electrical connection between the dummy bumps 44 and the internal circuit 34. For example, the dummy bumps 44 arranged so as to avoid the electrical connection between the dummy bumps 44 and all of the first lines 48 and all of the second lines 50.

As shown in FIG. 4, a resin 54 such as a thermoplastic resin or a thermosetting resin which works as an adhesive agent is interposed between the integrated circuit chip 28 and the liquid crystal display panel 10. Conductive particles 56 are dispersed in the resin 54 thus forming an anisotropic conductive film. The conductive particles 56 in the anisotropic conductive film are interposed between the plurality of first electrode terminals 40 and the plurality of first lines 48. The conductive particles 56 are also interposed between the plurality of second electrode terminals 42 and the plurality of second lines 50. The conductive particles 56 are also interposed between the dummy bump 44 and the land 52. To bring the conductive particles 56 into a proper collapsed state, a value of a load of a pressure bonding head which applies pressure to the integrated circuit chip 28 is set to an optimum numerical value (for example, 100N to 300N) depending on a chip size, the bump arrangement, an area of the bump and the like.

According to this embodiment, the dummy bumps 44 function as spacers thus preventing the deflection of the integrated circuit chip 28 and thereby the occurrence of electrical connection failure can be prevented. Accordingly, it is unnecessary to lower an applied load value of a pressure bonding head and hence, the proper electrical connection can be ensured.

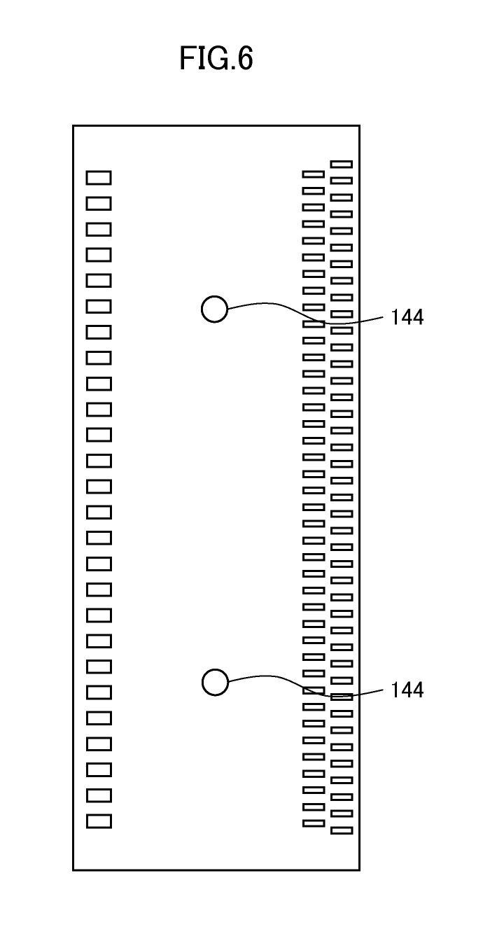

FIG. 6 is a view showing a modification of the embodiment of the invention. Although the dummy bump 44 shown in FIG. 3 has a square planar shape, a dummy bump 144 shown in FIG. 6 has a circular planar shape. In place of such shapes, other shapes (such as a rectangular shape) may be used as the planar shape of the dummy bump. This modification is substantially equal to the embodiment with respect to other constitutions, the manner of operation and the advantageous effects described above.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a display panel which has a display region;
a wiring pattern which is formed on the display panel; and
an integrated circuit chip which includes an internal circuit and is mounted on the display panel, wherein
the integrated circuit chip is configured such that the integrated circuit chip has a back surface including a first side and a second side which are arranged opposite to each other, the first side is arranged adjacent to the display region, and the integrated circuit chip includes: a plurality of first electrode terminals which are arranged on an edge portion along the first side and are electrically connected to the internal circuit; a plurality of second electrode terminals which are arranged on an edge portion along the second side and are electrically connected to the internal circuit; and a first bump which is arranged between the plurality of first electrode terminals and the plurality of second electrode terminals on the back surface thereof,
the wiring pattern includes: a plurality of first lines which are electrically connected to the plurality of first electrode terminals below the back surface of the integrated circuit chip and extend in a direction toward the display region outside the integrated circuit chip; and a plurality of second lines which are electrically connected to the plurality of second electrode terminals below the back surface of the integrated circuit chip and extend in a direction opposite to the display region outside the integrated circuit chip, and
the first bump is arranged with at least one of no electrical connection to any one of the first lines or any one of the second lines and no electrical connection to the internal circuit.

2. The display device according to claim 1, wherein in a state where the back surface is divided into four regions by evenly dividing a distance between the first side and the second side by four, the plurality of first electrode terminals are arranged in the region closest to the first side, the plurality of second electrode terminals are arranged in the region closest to the second side, and the first bump is arranged in two remaining regions.

3. The display device according to claim 1, wherein in a state where the back surface is divided into eight regions by evenly dividing a distance between both ends of the first side and the second side by eight, the first bump is arranged in second and third regions and in sixth and seventh regions as counted from either of said both ends.

4. The display device according to claim 1, wherein the wiring pattern further includes a land which is arranged away from the plurality of first lines and the plurality of second lines, and the land is arranged within a region where the land faces the back surface of the integrated circuit chip, and
the land is electrically connected with the first bump.

5. The display device according to claim 1, wherein the display device further comprises: conductive particles which are interposed between the plurality of first electrode terminals and the plurality of first lines as well as between the plurality of second electrode terminals and the plurality of second lines respectively.

6. The display device according to claim 4, wherein the display device further comprises: conductive particles which are interposed between the plurality of first electrode terminals and the plurality of first lines as well as between the plurality of second electrode terminals and the plurality of second lines respectively; and
conductive particles which are interposed between the first bump and the land.

7. The display device according to claim 1, wherein the plurality of first electrode terminals and the plurality of second electrode terminals form second bumps, and
the first bump is formed using the same material as the second bumps and has the same height as the second bumps.

8. The display device according to claim 1, wherein the internal circuit includes an active element.

9. The display device according to claim 1, wherein the first bump is arranged so as to avoid the electrical connection between the first bump and all of the first lines and all of the second lines.

10. The display device according to claim 1, wherein the first bump is arranged so as to avoid the electrical connection between the first bump and the internal circuit.

11. The display device according to claim 1, wherein a resin is interposed between the integrated circuit chip and the display panel.

12. The display device according to claim 2, wherein in a state where the back surface is divided into eight regions by evenly dividing a distance between both ends of the first side and the second side by eight, the first bump is arranged in second and third regions and in sixth and seventh regions as counted from either of said both ends.
